(19) United States
(12) Patent Application Publication
(10) Pub. No.: US 2019/0385878 A1
(43) Pub. Date: Dec. 19, 2019

(54) LIQUID CRYSTAL PANEL PACKAGE WITH WATER ABSORPTION ABILITY

(71) Applicant: HUIZHOU CHINA STAR OPTOELECTRONICS TECHNOLOGY CO., LTD., Huzhou Guangdong (CN)

(72) Inventor: Chengling LV, Huizhou Guangdong (CN)

(21) Appl. No.: 15/752,704

(22) PCT Filed: Jan. 18, 2018
(86) PCT No.: PCT/CN2018/073275

§ 371 Date: Feb. 14, 2018

(30) Foreign Application Priority Data
Dec. 25, 2017 (CN) 201711420922.8

(51) Int. Cl. H01L 21/673; G02F 1/1333

(52) U.S. Cl. CPC H01L 21/67366; G02F 1/1333; H01L 21/67389

(57) ABSTRACT

A liquid crystal panel package with water absorption ability is provided and comprises a box body and a water absorbent, wherein a containing groove is formed on the box body, the water absorbent is disposed within the containing groove and expands to partially protrude out of the containing groove after absorbing moisture in air, and the protruded part of the water absorbent is configured to abut another liquid crystal panel package stacked with the box body. The liquid crystal panel package with water absorption ability in the disclosure provides the water absorbent on box body so that the water absorbent expands and closely contacts with another liquid crystal panel package stacked thereon after absorbing moisture to fully fill the gap between the stacked two box bodies, and thereby prevents moisture from entering the package.

### RELATED APPLICATIONS

The present application is a National Phase of International Application Number PCT/CN2018/073275, filed Jan. 18, 2018, and claims the priority of China Application No. 201711420922.8, filed Dec. 25, 2017.

### FIELD OF THE DISCLOSURE

The disclosure relates to a liquid crystal panel processing field, and more particularly to a liquid crystal panel package with water absorption ability.

### BACKGROUND

At present, the most commonly used materials for the packaging of open cells are foam cushioning materials, such as Expandable Polyethylene (EPE) and Expanded polypropylene (EPP). The packaging method is basically a sealed way, that is, closely stacking each box, wrapping in the periphery of the stack with a stretch film, and covering the polyethylene (PE) waterproof film on the top. However, it is found that, after a product is shipped to and unpacked at a destination, mist or water droplets sometimes are formed inside the stretch film or even inside the box. These water mist or water droplets could result in the problem, such as short-circuit, of the electronic devices on the liquid crystal panels, and therefore the reliability is reduced.

The reason for the above problems is that there are manufacturing tolerances in the box, and a certain gap is formed after stacking. Water vapor in the external environment could entering the package through the stretch film and the gap between the boxes. At present, the common practice is to place desiccant in the box to absorb the moisture in the box, but the effect is normal. If the external water vapor can be prevented from infiltrating into the box and a structure capable of absorbing moisture can be provided on the path of infiltration of water vapor, the phenomenon of water mist or water droplets in the box will be greatly reduced.

### SUMMARY

The technique problem to be solved by the present disclosure is to overcome the drawbacks of the existed technology and provide a liquid crystal package to prevent the external moisture from entering the package.

In order to achieve the object above, the present disclosure adopts the technique solutions below:

A liquid crystal panel package with water absorption ability, comprising a box body and a water absorbent, wherein a containing groove is formed on the box body, the water absorbent is disposed within the containing groove and expands to partially protrude out of the containing groove after absorbing moisture in air, and the protruded part of the water absorbent is configured to abut another liquid crystal panel package stacked with the box body.

In one embodiment, the containing groove is formed on a surface of the box body, the surface faces the aforementioned another liquid crystal panel package, and a direction in which an opening of the container groove faces is parallel to a direction in which the box body and the aforementioned another liquid crystal panel package are stacked.

In one embodiment, a number of the containing groove and a number of the water absorbent are both plural.

In one embodiment, an inner wall of the containing groove is provided with a protrusion.

In one embodiment, an angle between an inner wall and a bottom surface of the containing groove is an acute angle.

In one embodiment, an inner wall of the containing groove is provided with a concave portion, and, after the water absorbent absorbs moisture and expands, a part of the expanded water absorbent fills into the concave portion.

In one embodiment, a number of the concave portion is two, and the two concave portions are formed respectively on opposite two inner walls of the containing groove.

In one embodiment, a material of the water absorbent is superabsorbent resin material,

The liquid crystal panel package with water absorption ability disclosed in the disclosure provides the water absorbent on box body so that the water absorbent expands and closely contacts with another liquid crystal panel package stacked thereon after absorbing moisture to fully fill the gap between the stacked two box bodies, and thereby prevents moisture from entering the package.

### BRIEF DESCRIPTION OF THE DRAWINGS

FIG. 1 is a schematic diagram of the box body according to the first embodiment of the present disclosure.

FIG. 2 is a cross-sectional diagram of the liquid crystal panel package according to the first embodiment of the present disclosure.

FIG. 3 is a cross-sectional diagram of the liquid crystal panel package after absorbing moisture according to the first embodiment of the present disclosure.

FIG. 4 is another cross-sectional diagram of the liquid crystal panel package according to the first embodiment of the present disclosure.

FIG. 5 is a cross-sectional diagram of the liquid crystal panel package according to the second embodiment of the present disclosure.

FIG. 6 is a cross-sectional diagram of the liquid crystal panel package after absorbing moisture according to the second embodiment of the present disclosure.

FIG. 7 is a cross-sectional diagram of the liquid crystal panel package according to the third embodiment of the present disclosure.

FIG. 8 is a cross-sectional diagram of the liquid crystal panel package after absorbing moisture according to the third embodiment of the present disclosure.

FIG. 9 is a cross-sectional diagram of the liquid crystal panel package according to the fourth embodiment of the present disclosure.

FIG. 10 is a cross-sectional diagram of the liquid crystal panel package after absorbing moisture according to the fourth embodiment of the present disclosure.

### DETAILED DESCRIPTION OF PREFERRED EMBODIMENTS

The objects, technique solutions and advantages of the embodiments of the present disclosure will be clearly and fully described below accompanying with the drawings of the embodiments. Obviously, the embodiments described below are only for explaining but not for limiting the present invention.

### First Embodiment

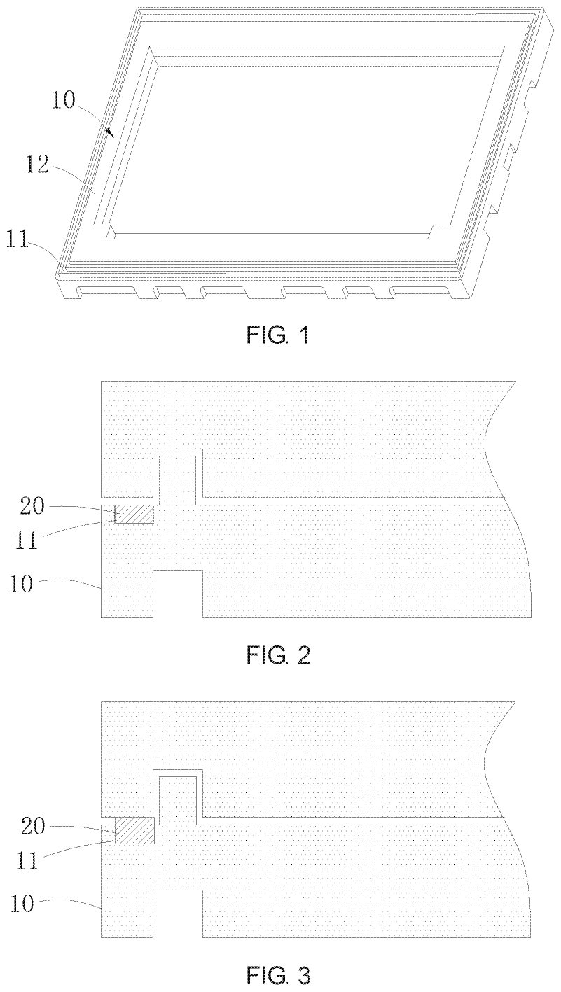

As shown in FIG. 1, FIG. 2 and FIG. 3, the liquid crystal panel package with water absorption ability in the present embodiment comprises a box body 10 and a water absorbent 20, a containing groove 11 is formed on the box body 10, and the water absorbent 20 is disposed within the containing groove 11. After absorbing moisture in air, the water absorbent 20 expands and a part of the water absorbent 20 protrudes out of the containing groove 11. In a sale package of the liquid crystal panels, a plurality of packages are stacked sequentially and the protruded part of the water absorbent 20 protruding out of the containing groove 11 is configured to abut another liquid crystal panel package stacked with the box body 10. In one aspect, the water absorbent 20 absorbs water and, in another aspect, the water absorbent 20 full fills the gap existed between the box body 10 and other liquid crystal panel packages to prevent the moisture in the environment from entering the box body 10 from the gap, so that damages of the electronic devices of the liquid crystal panel are prevented.

Specifically, as shown in FIG. 2, the containing groove 11 is formed on a surface of the box body 10, and the surface with the containing groove 11 faces another liquid crystal panel package. In one embodiment, the aforementioned another liquid crystal panel package is disposed above the box body 10, and therefore the containing groove 11 is disposed at the top surface of the box body 10. In other embodiments, the aforementioned another liquid crystal panel package could be disposed below the box body 10, and therefore the containing groove 11 is disposed at the bottom surface of the box body 10. Furthermore, an opening direction in which an opening of the container groove 11 faces is parallel to a stacking direction in which the box body 10 and the aforementioned another liquid crystal panel package are stacked, so that the part of the water absorbent 20 protruding out of the containing groove 11 could be extended along the stacking direction and the water absorbent 20 is contacted with other liquid crystal panel packages in the stacking direction to benefit assembly and disassembly of the packages. Once the opening direction of the containing groove 11 is perpendicular to the stacking direction, horizontal pushing between the box body 10 and other liquid crystal panel packages would occur to hinder the assembly and disassembly of the package.

Specifically, the box body 10 has a frame-like structure, preferably a rectangular frame, the containing groove 11 is a loop structure arranged around the boundary frame 12 of the box body 10. Correspondingly, the shape of the water absorbent 20 is matched with the loop structure of the containing groove 11. Therefore, after the water absorbent 20 absorbs water and expands, the water absorbent 20, the box body 10 and other liquid crystal panel packages stacked above the box body 10 form a sealing structure to prevent outside moistures from entering the box.

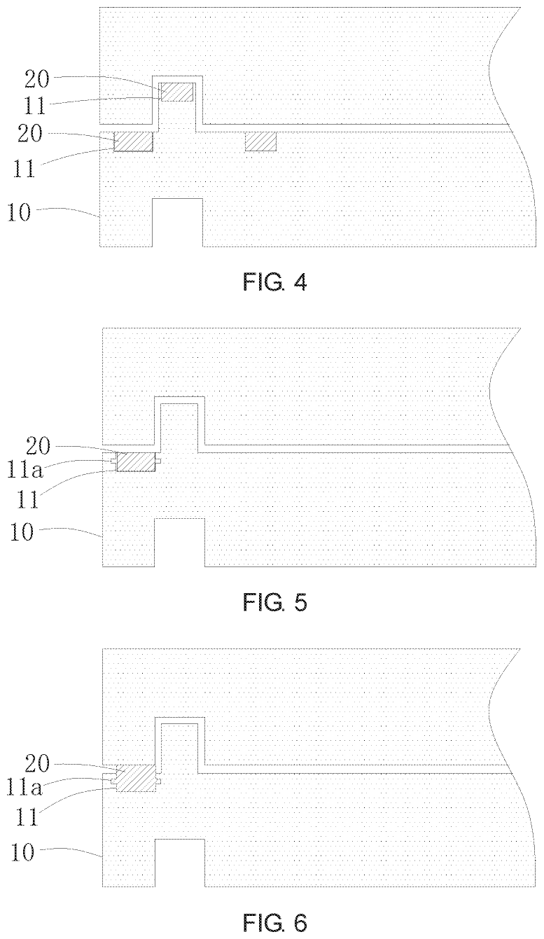

In one embodiment, there are a plurality of containing groove 11. As shown in FIG. 4, the number of the containing groove 11 is three, and the three containing grooves 11 are with different sizes and disposed sequentially from inside to outside. The water absorbent 20 in each containing groove 11 expands and contacts with the packages above the water absorbent 20 after absorbing water to achieve a better sealing effect.

As a preferred embodiment, a material of the water absorbent 20 is selected to be superabsorbent resin material, which provides better absorption and high water-retention and would not release the absorbed water while being squeezed. In addition, the superabsorbent resin material is with good elasticity after absorbing water, so that the water absorbent 20 is ensured to be closely contact with the packages and is used as a buffer during transporting the package.

### Second Embodiment

As shown in FIG. 5 and FIG. 6, the differences between the liquid crystal panel package with water absorption ability in the present embodiment and the first embodiment are: the inner walls of the containing groove 11 is provided with concave portions 11a, and a part of the water absorbent 20 extends along the direction parallel to the stacking direction and another part of the of the water absorbent 20 extends along the direction perpendicular to the stacking direction to fill into the concave portions 11a after the water absorbent 20 absorbs water and expands, which is beneficial to the fixing of the water absorbent 20 and prevents falling during assembling/disassembling processes and transporting.

In one embodiment, the amount of the concave portion 11a is two and the two concave portion 11a are provided respectively on opposite two inner walls of the containing groove 11, so that the water absorbent 20 can be fixed on the opposite two inner walls to further prevent the water absorbent 20 from falling off from the box body 10.

### Third Embodiment

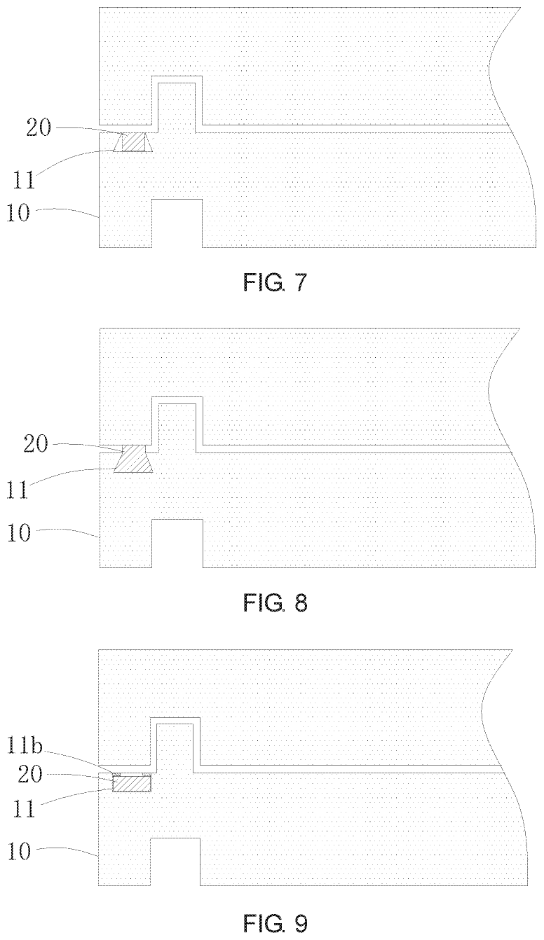

As showing in FIG. 7 and FIG. 8, the differences between the liquid crystal panel package with water absorption ability in the present embodiment and the first embodiment are: the inner walls of the containing groove 11 are inclined, and angles between the inner walls and a bottom surface of the containing groove are acute angles, that is, the size of the bottom of the containing groove 11 is larger than the size of the opening of the containing groove 11. After the water absorbent 20 absorbs water and expands, the part of the water absorbent 20 within the containing groove 11 abuts the inclined inner walls in the stacking direction to prevent the water absorbent 20 from falling off.

In other embodiment, the inner walls of the containing groove 11 could be a ladder shape, and, after the water absorbent 20 absorbs water and expands, the containing groove 11 could limit movement of the water absorbent 20 in the stacking direction,

### Fourth Embodiment

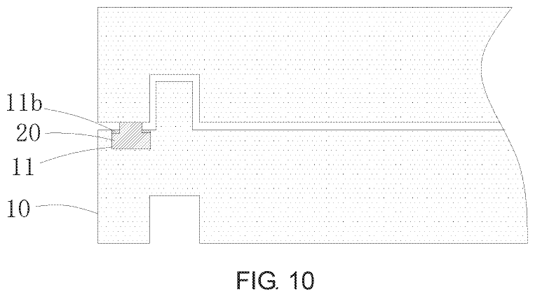

As shown in FIG. 9 and FIG. 10, the differences between the liquid crystal panel package with water absorption ability in the present embodiment and the first embodiment are: the opposite inner walls of the containing groove 11 are provided with protrusions 11b, and the protrusions 11b are arranged on a side of the inner walls near the opening of the containing groove 11. Before absorbing water, the water absorbent 20 is totally disposed under the protrusions 11b. After the water absorbent 20 expands, a part of the water absorbent 20 passes through between the two protrusions 11b and extends out of the containing groove 11. Therefore, the containing groove 11 could limit movement of the water absorbent 20 in the stacking direction to prevent the water absorbent 20 from falling off.

The liquid crystal panel package with water absorption ability disclosed in the disclosure provides the water absorbent on box body so that the water absorbent expands and closely contacts with another liquid crystal panel package stacked thereon after absorbing moisture to fully fill the gap between the stacked two box bodies, and thereby prevents moisture from entering the package.

The foregoing contents are detailed description of the disclosure in conjunction with specific preferred embodiments and concrete embodiments of the disclosure are not limited to the description. For the person skilled in the art of the disclosure, without departing from the concept of the disclosure, simple deductions or substitutions can be made and should be included in the protection scope of the application.

What is claimed is:

1. A liquid crystal panel package with water absorption ability, comprising a box body and a water absorbent, wherein a containing groove is formed on the box body, the water absorbent is disposed within the containing groove and expands to partially protrude out of the containing groove after absorbing moisture in air, and the protruded part of the water absorbent is configured to abut another liquid crystal panel package stacked with the box body.

2. The liquid crystal panel package with water absorption ability according to claim 1, wherein the containing groove is formed on a surface of the box body, the surface faces the another liquid crystal panel package, and a direction in which an opening of the container groove faces is parallel to a direction in which the box body and the another liquid crystal panel package are stacked.

3. The liquid crystal panel package with water absorption ability according to claim 2, wherein the containing groove is a loop structure arranged around the boundary frame of the box body.

4. The liquid crystal panel package with water absorption ability according to claim 3, wherein a number of the containing groove and a number of the water absorbent are both plural.

5. The liquid crystal panel package with water absorption ability according to claim 3, wherein an angle between an inner wall and a bottom surface of the containing groove is an acute angle.

6. The liquid crystal panel package with water absorption ability according to claim 3, wherein an inner wall of the containing groove is provided with a concave portion, and, after the water absorbent absorbs moisture and expands, a part of the expanded water absorbent fills into the concave portion.

7. The liquid crystal panel package with water absorption ability according to claim 6, wherein a number of the concave portion is two, and the two concave portions are formed respectively on opposite two inner walls of the containing groove.

8. The liquid crystal panel package with water absorption ability according to claim 1, wherein a material of the water absorbent is superabsorbent resin material.

9. The liquid crystal panel package with water absorption ability according to claim 3, wherein an inner wall of the containing groove is provided with a protrusion.

10. The liquid crystal panel package with water absorption ability according to claim 9, wherein an angle between the inner wall and a bottom surface of the containing groove is an acute angle.

11. The liquid crystal panel package with water absorption ability according to claim 10, wherein the inner wall of the containing groove is provided with a concave portion, and, after the water absorbent absorbs moisture and expands, a part of the expanded water absorbent fills into the concave portion.

12. The liquid crystal panel package with water absorption ability according to claim 11, wherein a number of the concave portion is two, and the two concave portions are formed respectively on opposite two inner walls of the containing groove.
